(19) United States
(12) Patent Application Publication
(10) Pub. No.: US 2009/0174988 A1
(43) Pub. Date: Jul. 9, 2009

(54) Holding device for mounting a display unit, a display unit and display device

(76) Inventor: Martin Roehl, Hildesheim (DE)

Correspondence Address: KENYON & KENYON LLP, ONE BROADWAY, NEW YORK, NY, 10004, US

(21) Appl. No.: 11/919,842

(22) PCT Filed: Apr. 7, 2006
(86) PCT No.: PCT/EP2006/061453

§ 371 Date: Jan. 26, 2009

(30) Foreign Application Priority Data
May 4, 2005 (DE) 10 2005 021 393.6

(51) Int. Cl. H05K 7/00

(52) U.S. Cl. 361/679.01; 361/825

(57) ABSTRACT

A holding device for installing a display unit, having a holding element and receiving elements connected to the holding element, which have essentially wedge- or v-shaped recesses, which are used to accommodate axial sections of the display unit having a corresponding wedge-type design; display unit and mounting system. It is advantageous that the display unit and holding device are separated in a simple manner. This separation in turn has the advantage of facilitating the installation of the display device and, if required, also a subsequent de-installation of the display unit or the entire display device. In particular, this is achieved in that the holding device for accommodating the monitor or the display unit is mounted separately therefrom, and the monitor is able to be installed in the holding device at a later time. A holding device for installing the display unit, which includes a holding element and receiving elements connected to the holding element, which have essentially wedge- or v-shaped recesses that are provided to receive correspondingly wedge-shaped axial sections of the display unit. Even after several installation and/or de-installation cycles, this allows a play-free and thus rattle-free installation of the display unit.

### FIELD OF THE INVENTION

The present invention is based on a display device, a display unit, and a console for mounting a display unit.

### BACKGROUND INFORMATION

Overland buses equipped with a video system are often provided with LCD (liquid crystal display) monitors, which are able to be extended and retracted automatically with the aid of a tilting device. The tilting device is supported in a holder, which permits the installation of the unit, made up of tilting device and monitor, on a roof construction of an overland bus. In conventional display devices of this type, monitor or display unit, the tilting device or tilting mechanism, and the holder form a structural unit, which is jointly installed in the vehicle.

This has the disadvantage that installation and de-installation of the display device becomes more difficult due to its great weight. Since the holder is mounted on a sturdy element, in particular steel elements of the roof construction of an overland coach, for example, the installation of the entire display device is carried out in a contaminated environment. As a result, there is the risk of soiling of and damage to the actual sensitive display unit, i.e., especially the LC display. Since the roof lining is installed only after the holder has been mounted, it must later be de-installed if work that necessitates de-installation of the monitor is required on this display device.

### SUMMARY OF THE INVENTION

The present invention has the advantage that display unit and holder are separated in a simple manner. This separation in turn has the advantage that the installation of the display device and, if required, also a subsequent dismantling of the display unit or the entire display device is facilitated. This is achieved by, in particular, the possibility of installing the holder for supporting the monitor or the display unit separately therefrom, and fixing the monitor in place in the holder at a later time. According to the present invention, a holding device for installing the display unit is provided, which includes a holding element and receiving elements connected to the holding element, which have essentially wedge- or v-shaped recesses that are provided to receive correspondingly wedge-shaped axial sections of the display unit. This allows a play-free and thus rattle-free installation of the display unit even after several installation and/or de-installation cycles.

The holder advantageously includes rotatably supported gripping levers for bracing the axial sections in the recesses by exerting a force on the axial section essentially in the direction of the tapered regions of the wedge-shaped recesses. Possible play and/or tolerances may thereby be compensated for.

In an advantageous manner, the gripping levers have stop springs, which lock into place in additional recesses of the receiving elements of the holder once the gripping levers are latched. This allows an especially rapid and uncomplicated installation of the display unit in that the display unit is already fixed in place simply by latching the gripping levers.

In an advantageous manner, additional means for bracing the gripping levers are provided. These may advantageously be embodied as clamping bolts and preferably brace the clamping lever with respect to the holding element of the holding device. Possible play and/or tolerances may be compensated for in this manner.

Also advantageous are hook-shaped extensions of the gripping levers at their ends lying opposite the bearing assembly, for the temporary support of the display unit, in particular for installation purposes.

### BRIEF DESCRIPTION OF THE DRAWINGS

FIG. 1 shows a display unit and a console according to the present invention for mounting and holding the display unit.

FIG. 2 shows a section through the axis of the display unit as well as the section of the console that is important for supporting the display unit.

FIG. 3 shows a console and display unit in the assembled state.

### DETAILED DESCRIPTION

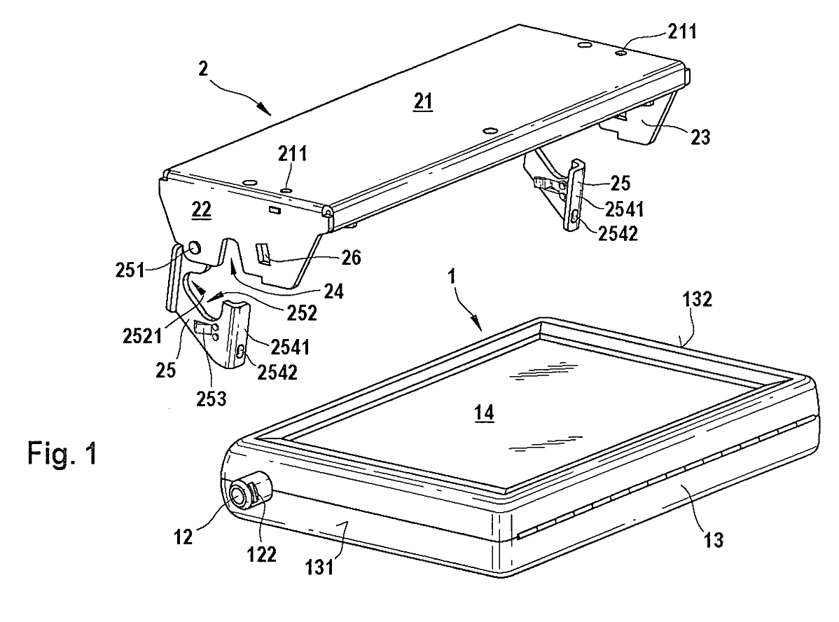

A display unit 1 and a holding device 2, in the following text also console 2, for receiving and supporting display unit 1 are illustrated in FIG. 1.

Display unit 1 has a housing 13 in which, for one, an already known tilting device for tilting entire display unit 1 is disposed, and in which actual display element 14, i.e. the LC display or a TFT display or similar device, for instance, is disposed in addition.

The tilting device is connected to an axle or axial sections. These laterally project from housing 13 in the form of axial sections 12 from opposite sides of housing 13. To tilt monitor 1, the tilting mechanism applies a torque on the axle or axial sections 12, which essentially results from the weight of display unit 1 and the lever arm acting on axial sections 12. This torque must be absorbed by holding device 2.

Holding device 2 has a holding element 21, which is used to mount holding device 2 itself, for instance on the roof construction of an overland coach. In the exemplary embodiment illustrated in FIG. 1, holding element 21 is designed as a disk-shaped element. However, alternative developments are possible as well and are encompassed within the scope of the present invention.

Holding device 2 also includes two receiving elements 22 and 23, which are connected to holding element 21. In the case at hand, it is a stamped sheet-metal component in which receiving elements 22 and 23 are formed as sheet metal tabs bent away from holding element 21. Each of these forms a right angle together with holding element 21, so that holding device 2 has an essentially U-shaped cross section over all, such that receiving elements 22 and 23 form the legs of the “U”, and holding element 21 the base of the “U”.

In the following analysis it is assumed that holding element 21 is screwed to the roof construction of an overland coach or, for instance, a rail train or similar, and that receiving elements 22 and 23 point downward in this mounted state.

At their lower edges, i.e., the edges facing away from holding element 21, receiving elements 22 and 23 each have a recess 24, recesses 24 being substantially identical. Recesses 24 are open toward the bottom, i.e., toward the lower edge of receiving elements 22 and 23 (243).

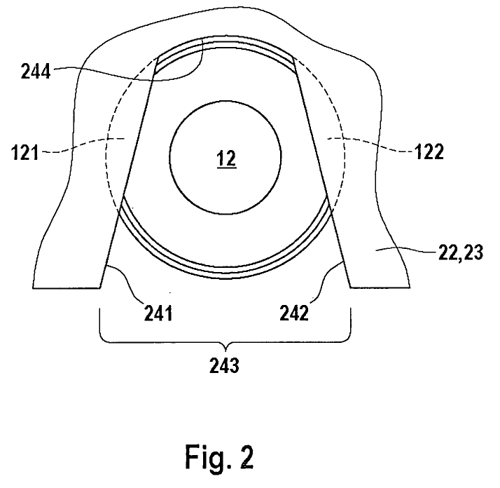

Recesses 24 (FIG. 2) have contact edges 241 and 242, which delimit recesses 24 and extend in the form of a wedge or “v” toward one another in an upward direction, i.e., in the direction of holding element 21. Recesses 24 thus form a gap, which tapers in an upward direction or from its opening 243, and is delimited by contact edges 241 and 242. In the upward direction, this gap is delimited by a circular-arc segment 244. A different type of termination of the gap is possible as well.

Described recesses 24 accommodate axial sections 12 of display unit 1, which project from side faces 131 and 132 of a housing 13 of display unit 1 lying opposite one another. Axial sections 12 have an essentially round cross section. For the purpose of introduction into recesses 24 of holding device 2 and for rotation-proof clamping and bracing of axial sections 12 in wedge-shaped recesses 24 of receiving elements 22 and 23 of holding device 2, grooves 121 and 122 have been cut out or introduced in some other manner; these are disposed at an angle with respect to each other, the angle corresponding to the angle of contact edges 241 and 242 of wedge-shaped recesses 24 with respect to each other. Essential here is that axial sections 12 sections in which opposite lying side faces 121 and 122 of axial sections 12 have at least approximately the same angle with respect to each other as contact edges 241 and 242 of recesses 24. These sections need not necessarily be in the form of grooves in the axial sections. However, this specific embodiment as grooves has the particular advantage that display unit 1 is protected against lateral displacement in recesses 24 along axial sections 12.

To mount display unit 1, its axial sections 12 projecting from housing 13 on the right and left side are inserted into recesses 24 of holding device 2 so that grooves 121 and 122 and correspondingly formed contact faces 121 and 122 are aligned parallel to corresponding contact edges 241 and 242 of recesses 24. In the process, axial sections 12 are pushed in the direction of the tapered region of recesses 24, i.e., in an upward direction, until it exerts a counter pressure on contact faces 121 and 122, i.e., grooves 121 and 122, via contact edges 241 and 242, which acts counter to the direction of insertion.

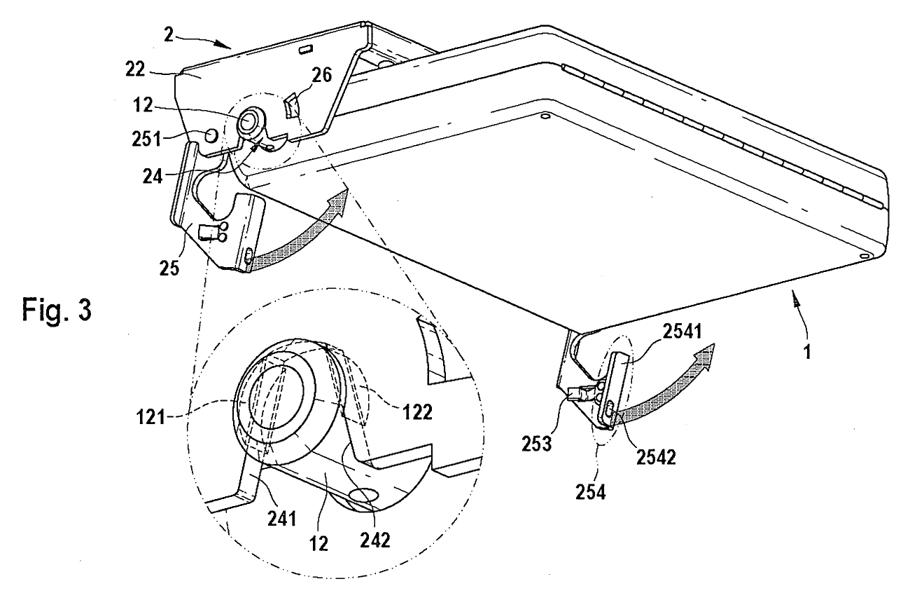

Gripping levers 25 disposed on receiving elements 22 and 23 so as to be rotatable, via a hinge 251 in each case, are used to fixate and support display unit 1 in this position. Gripping levers 25 are able to rotate in a plane parallel to receiving elements 22, 23. Gripping levers 25 have a connecting link 252 that in turn has a first end section 2521 facing hinge 251, which is used to fix axial sections 12 in place in recesses 24. This end section 2521 of connecting link 252 has a basically circular form, the radius of the circular arc essentially corresponding to the radius of axial sections 12. If gripping lever 25 is swiveled along the direction of the arrow (FIG. 3), then first end section 2521 of connecting link 252 is pressed against axial section 12 from below, and axial section 12 is thereby pressed into recess 24. Due to the wedge-shaped design of recess 24 and the corresponding contact faces 121 and 122 of axial sections 12, axial section 12 is therefore wedged into and fixed in place in the recess. Any play of axial section 12 in recess 24 and thus possible rattling noises are avoided in this manner.

Gripping lever 25 has a spring segment 253, which snaps into place into a corresponding additional recess 26 of holding element 22 and 23 when the gripping lever is closed along the direction of the arrow in FIG. 3, thereby locking gripping lever 25 in the closed state. In this way display unit 1 is securely mounted in holding device 2.

At its end facing away from hinge 251, gripping lever 25 has a hook-shaped extension 254, which is open on top in the unlocked state of gripping lever 25. One use of extension 254 is the bracing of gripping lever 25.

To this end, extension 254 has a beveled region 2541, which is disposed perpendicular to the tilting direction and positioned essentially parallel to holding element 21 in the closed state. Beveled region 2541 has a bore 2542 for this purpose, through which a clamping bolt may be guided. This clamping bolt engages with a thread 211 of holding element 21, so that gripping lever 25 is pulled towards holding element 21 along the direction of the arrow when the clamping bolt is tightened. This not only constitutes an additional safety mechanism for gripping lever 25 in the closed state but also makes it possible to compensate for play or tolerances in the production of v-shaped recess 24 of holding elements 22, 23 and/or grooves or contact faces 121 and 122 of axial sections 12.

Hook-shaped extension 254 also serves as resting place for display unit 1 for installation purposes. For instance, axial sections 12 are able to be placed in open gripping levers 25 where they are retained by hook-shaped extension 254. Display unit 1 is able to be wired in this position, for example, and the cables installed in a concealed manner. Only then will display unit 1 be fixed in place in its final position with the aid of gripping levers 25.

Connecting link 252 of gripping levers 25 is designed in such a way that axial sections 12 of display unit 1, provided it is situated in hook-shaped extensions 254, are automatically guided into their locked position, i.e., in the direction of the arrow in FIG. 3, along the connecting link to its end section 2521, and automatically guided into recesses 24 upon further rotation of gripping levers 25. This further facilitates the installation of display unit 1. To this end, connecting link 252 has an essentially smooth and straight characteristic in its center region, between the hook-shaped extension and its end section 2521. When gripping lever 25 is rotated, an excessive height of the region of connecting link 252 close to the hook comes about relative to its end section 2521, so that the described sliding of axial sections 12 in the direction of end section 2521 takes place.

1-7. (canceled)

8. A holding device for installing a display unit, comprising:
a holding element; and
receiving elements connected to the holding element, which have substantially wedge-shaped or v-shaped recesses, which accommodate axial sections of the display unit having a corresponding wedge-type design.

9. The holding device according to claim 8, further comprising rotatably supported gripping levers for clamping the axial sections into the recesses by exerting a force on the axial sections substantially in a direction of tapered regions of the wedge-shaped recesses.

10. The holding device according to claim 9, further comprising stop springs situated on the gripping levers, which lock into place in additional recesses of the receiving elements when the gripping levers are closed.

11. The holding device according to claim 9, further comprising means for additional bracing of the gripping levers, for bolting the gripping levers to the holding element.

12. The holding device according to claim 9, wherein the gripping levers have hook-shaped extensions at their ends lying opposite their support, for a temporary holding of the display unit, for installation purposes.

13. A display unit for installation in a holding device, comprising:
axial sections having wedge-shaped or v-shaped beveled areas for introduction into correspondingly formed wedge-shaped or v-shaped recesses of the holding device.

14. A system for installing a display unit, comprising:
a holding device including a holding element and receiving elements connected to the holding element, which have wedge-shaped or v-shaped recesses; and
a display unit including axial sections having wedge-shaped or v-shaped beveled areas for introduction into corresponding recesses of the holding device.
